(19) United States
(12) Patent Application Publication
(10) Pub. No.: US 2013/0153016 A1
(43) Pub. Date: Jun. 20, 2013

(54) Solar Cell Flip Chip Package Structure and Method for Manufacturing the same

(71) Applicant: Shao-Pin Ru, New Taipei City (TW)

(72) Inventor: Shao-Pin Ru, New Taipei City (TW)

(73) Assignee: TONG HSING ELECTRONIC INDUSTRIES, LTD., Taipei City (TW)

(21) Appl. No.: 13/330,674

(22) Filed: Dec. 20, 2011

(51) Int. Cl. H01L 31/0224; H01L 31/02; H01L 31/18

(52) U.S. Cl. 136/256; 438/64; 136/252; 257/E31.001

(57) ABSTRACT

The present invention provides a solar cell flip chip package structure, comprising: a substrate having a first surface, a second surface and an opening extending from the first surface to the second surface; a conducting layer disposed on the first surface of the substrate; a solar cell flip chip bonded on the conducting layer; a transparent layer attached on the second surface of the substrate; and a storage space formed between the opening extending from the first surface to the second surface, the solar cell flip chip and the transparent layer.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

This invention relates to a chip package structure, and more particularly, to a flip chip package structure which is used for CPV, concentration photo-voltaic Systems.

2. Description of Related Arts

There are only limited resources available on the earth. Human beings are encountering with the difficulty and embarrassment of constantly consumed and gradually depleted energy resources. According to reports from energy-related journals, the exploitation of oil is estimated to terminate within next ten years. On the other hand, the use of nuclear energy would face the problem of nuclear waste disposal. Therefore, it has become a very important and pressing task to develop a new generation of energy sources.

Among a variety of renewable energy technologies, the application of solar photovoltaic energy has received particularly wide attention and deemed as the currently available most reliable new energy source. Meanwhile, the solar photovoltaic enabling the use of sunlight as the new energy source has simple structure without the risk of causing recycled pollution. Therefore, the solar photovoltaic energy is referred to as clean energy. Among the viable photovoltaic technologies, concentration solar cell has gained a lot of attention due to its high energy conversion efficiency recently. Thus, developing an easy-fabrication and easy-assemblage light-focusing package structure for a solar chip is also one of the important subjects in the fields concerned.

An example of prior art flip chip package structure is provided in U.S. Pat. No. 6,833,612 to Kinsman, the entirety of which is hereby incorporated by reference herein. In most traditional electro-optical flip chip package structures, the solder balls are used in Ball Grid Array (BGA) type packages for electrical interconnections due to the ease of implementation and low material cost. However, during the solder ball attachment process, it is very difficult to control the height of each solder ball accurately, especially for some specific applications which other components also need to be attached onto the printed circuit board (PCB) as solder balls through surface mount technologies (SMT), the non-consistent solder ball height is hardly to use. In addition, the electrical and thermal conductivity of solder ball are not as good as pure Copper, for image sensor or any other non-power-sensitive applications, this approach is acceptable, but for high-efficiency and high-reliable solar cell packages, the solder balls consumes more extra energy and degrades the photovoltaic conversion efficiency.

Another example of prior art ball grid array package is provided in U.S. Pat. No. 6,566,745 to Beyne, the entirety of which is hereby incorporated by reference herein. The package includes flip chip solder joints for electrical interconnection between an image sensor die and a glass substrate. Also, this package includes solder balls which serve as package's external terminals, as well as metal lines formed on the glass substrate for connecting the solder balls and flip chip solder joints. This package further includes a solder sealing ring having a closed loop configuration. In addition, the package includes epoxy sealing disposed about the solder sealing ring. However, for the specific dice which the backside of flip chip is also electrode and needs to be mounted onto the PCB as solder balls, the solder balls with non-consistent height make difficulty to have a well contact between the backside of flip chip die and board.

Another example of prior art sensor unit with a light-sensitive semiconductor element is provided in U.S. Pat. No. 6,885,107 to Kinsman, the entirety of which is hereby incorporated by reference herein. In which electrical traces are placed on a contacting unit or printed circuit board or conductive film, electrically coupled to the semiconductor element. However, the package's external terminals still use solder balls.

Another example of prior art photo sensor electronic package is provided in U.S. Pat. No. 7,038,287 to Kim, the entirety of which is hereby incorporated by reference herein. In which, at least one patterned metal layer is applied on a front surface of the substrate for making solder bump pads and interconnection lines connecting such solder bump pads. Then, at least one patterned passivation layer is applied on the patterned metal layer for protecting the interconnection lines formed thereby. The solder bump pads in the first set are relatively small for making interconnections to a photo-sensing semiconductor die 101. However, the package's external terminals are still solder balls, with non-consistent height and passable electrical and thermal performance.

Another example of prior art flip chip package structure is provided in U.S. Pat. No. 7,443,038 to Kinsman, the entirety of which is hereby incorporated by reference herein. In which, conductive traces are formed directly on the second surface of a transparent substrate and an image sensor chip is bonded to the conductive traces. Discrete conductive elements are attached to the conductive traces and extend below a back surface of the image sensor chip.

Moreover, in traditional solar cells, dust is easily adhered to the external mask due to the external mask being made of silica gel. After expose to the weather for a long period, the penetrability of the solar cells is further decreased because of the external mask atomized/deteriorated. Furthermore, in traditional solar cells, wire bonding is widely used for electrical connecting the chips to other circuits. Thus, the high-resistance wires with long and thin shape consume extra energy from optical power to electrical power, and also generate more heat during operation to degrade the efficiency of solar cell.

It is desirable, therefore, to provide a solar cell flip chip package structure with high photovoltaic conversion efficiency and for solving problems aforementioned.

### SUMMARY OF THE PRESENT INVENTION

One of objects of the present invention is to provide solar cell flip chip package structure with high photovoltaic conversion efficiency, which may be fabricated with IC fabrication process to simply the packaging process of a light-focusing solar cell.

To achieve the abovementioned object, the invention provides a solar cell flip chip package structure, comprising: a substrate having a first surface, a second surface and an opening extending from the first surface to the second surface; a conducting layer disposed on the first surface of the substrate; a solar cell flip chip bonded on the conducting layer; a transparent layer attached on the second surface of the substrate; and a storage space formed between the opening extending from the first surface to the second surface, the solar cell flip chip and the transparent layer.

Another embodiment of the invention provides a solar cell flip chip package structure, comprising: a substrate having a first surface, a second surface and an opening extending from the first surface to the second surface; a conducting layer disposed on the first surface of the substrate; a solar cell flip chip bonded on the conducting layer; a transparent layer formed by glass attached on the second surface of the substrate; and a storage space formed between the opening extending from the first surface to the second surface, the solar cell flip chip and the transparent layer.

Another embodiment of the invention provides a method for manufacturing solar cell flip chip package structure, comprising: forming a rectangular opening from a substrate; covering a first conducting layer on top surface of the substrate by electroplating; plating a surface finish layer on the first conducting layer; planting bumps on the surface finish layer for electrically conducting to a solar cell flip chip; dispensing glue on the second surface of the substrate; and adhering a transparent layer to the second surface of the substrate for covering on the rectangular opening.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

The details and technology of the present invention are described below with reference to the accompanying drawings:

### BRIEF DESCRIPTION OF THE DRAWINGS

The objects, spirits, and advantages of the preferred embodiments of the present invention will be readily understood by the accompanying drawings and detailed descriptions, wherein:

FIG. 1 is a perspective view showing the completed package structure of one embodiment of the present invention.

FIG. 2 is a top view showing the package structure of the present invention in the first manufacturing process.

FIG. 3 is a cross section of the package structure of the present invention in the manufacturing process after FIG. 2.

FIG. 4 is a cross section of the package structure of the present invention in the manufacturing process at the same time with FIG. 3.

FIG. 5 is a cross section of the package structure of the present invention in the manufacturing process after FIG. 4.

FIG. 6 is a cross section of the package structure of the present invention in the manufacturing process after FIG. 5.

FIG. 7 is a cross section of the package structure of the present invention in the manufacturing process after FIG. 6.

FIG. 8 is a cross section of the package structure of the present invention in the manufacturing process after FIG. 7.

### DETAILED DESCRIPTION OF THE PREFERRED EMBODIMENT

For clarity of disclosure, and not by way of limitation, the detailed description of the invention is divided into the subsections that follow.

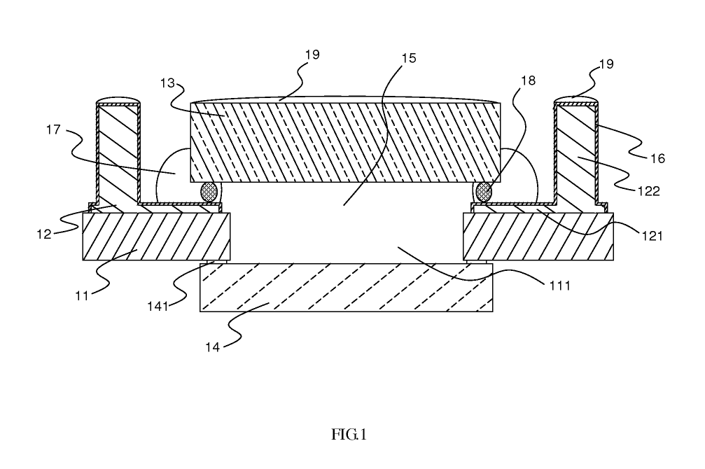

With reference to FIG. 1, this illustrates a perspective view showing the completed package structure of one embodiment of the present invention. The solar cell flip chip package structure 10 comprises a substrate 11, a conducting layer 12, a solar cell flip chip 13, a transparent layer 14 and a storage space 15. The substrate 11 has a first surface, such as top surface, a second surface, such as bottom surface, and an opening 111 extending from the first surface to the second surface. The conducting layer 12 is formed on the first surface of the substrate 11. The solar cell flip chip 13 is bonded on the conducting layer 12 and the transparent layer 14 is attached on the second surface of the substrate 11. Thus, the opening 111 extending from the first surface to the second surface is covered by the conducting layer 12, the solar cell flip chip 13 and the transparent layer 14. In the other words, the storage space 15, which is formed between the opening 111 extending from the first surface to the second surface, the solar cell flip chip 13 and the transparent layer 14, is therefore, sealed.

In FIG. 1, due to the mature process and cost-effectiveness being the two advantages of a ceramic substrate, the substrate 11 of the present invention is formed by ceramic, glass, or organic materials.

The conducting layer 12, which is used for conducting the solar cell flip chip 13 to other devices, comprises a copper trace 121 disposed on the first surface and a copper pillar 122. For SMT requirement, the height of plated copper pillars and the top side of flip chip shall be the same. Due to the heights of the copper pillar 122 and the height of the solar cell flip chip 13 are the same, the solar cell flip chip package structure 10 with solder pads 19 disposed on tops of the copper pillar 122 and the solar cell flip chip 13 is easier to be soldered on a printed circuit board (PCB) through surface mount technologies (SMT). The copper trace 121 and the copper pillar 122 are formed in one piece by electroplating for decreasing the total manufacturing process. The conducting layer 12 further comprises a surface finish layer 16, which is selected from a group consisting of Ag, Ag/Au, Ni/Au, Ni/Pd/Au, or any combination of the group that are widely used for surface finish, covered on the copper trace 12 and the copper pillar 122 for isolating the conducting layer 12 with external dirt.

In FIG. 1, the solar cell flip chip 13 further comprises at least one contact point for connecting to the conducting layer 12. Each of the at least one contact point is a bump 18 selected from a group consisting of Au, Cu, Ag, Al, Sn or any combination of the group that is widely used for interconnection. Each of the at least one contact point (bump 18) further comprises a dam sealing structure 17. The dam sealing structure 17 increases the adhesion between Each of the at least one contact point (bump 18) and the conducting layer 12. The gold stud bump flip chip process bumps die by a modified standard wire bonding technique. This technique makes a gold ball for wire bonding by melting the end of a gold wire to form a sphere. The gold ball is attached to the chip bond pad as the first part of a wire bond. To form gold bumps instead of wire bonds, wire bonders are modified to break off the wire after attaching the ball to the chip bond pad. The gold ball, or “stud bump” remaining on the bond pad provides a permanent connection through the aluminum oxide to the underlying metal. The gold stud bump process is unique in being readily applied to individual single die or to wafers. Gold stud bump flip chips may be attached to the substrate bond pads with adhesive or by thermosonic gold-to-gold interconnection.

Due to the transparent layer 14 being formed by glass, dust on the transparent layer 14 is easily to clean and atomization/deterioration on the transparent layer 14 is on rare occasions happened. Moreover, replacing wire bonding in traditional arts by bumps with thin and short surface area and low contact resistance, the impedance of the present invention is 500 times less than the traditional arts'. Therefore, problems in traditional arts are all solved.

In FIG. 1, the solar cell flip chip package structure 10 further comprises a conducting circuit (not shown) formed on the second surface of the substrate 11. The conducting circuit (not shown) is used for expanding the use of the solar cell flip chip package structure 10 or protecting the substrate 11. For example, the conducting circuit (not shown) comprises a surface finish layer. Moreover, the transparent layer 14 is formed by glass with high transparency.

There is a glue layer 141, such as UV epoxy, disposed between the substrate 11 and the transparent layer 14 for increasing the combination of the solar cell flip chip package structure 10. The storage space 15 is further filled to the full with an optical epoxy or silicon adhesive that can enhance the adhesion among glass, substrate, and solar cell flip chip. Thus, the efficiency of light to electricity will be improved.

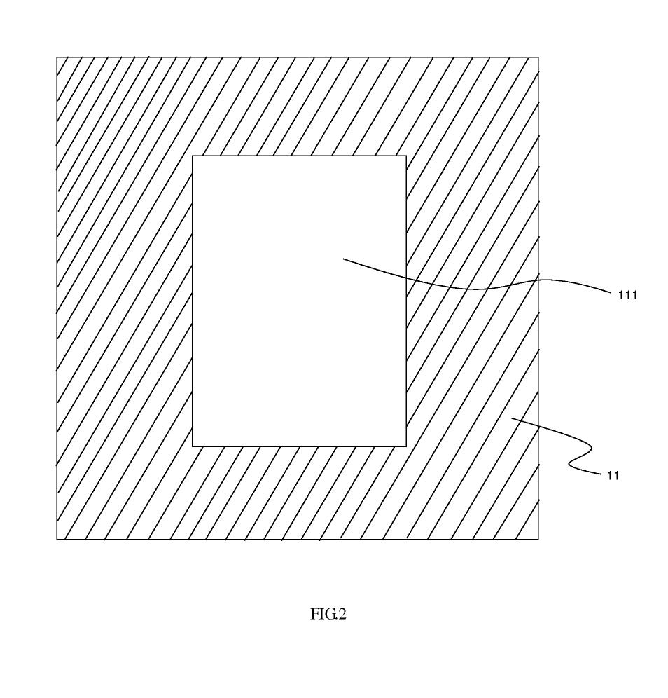

With reference to FIG. 2, this illustrates a top view showing the package structure of the present invention in the first manufacturing process. As shown, the rectangular opening 111 of the present invention is formed through the ceramic substrate 11 by laser drilling. The rectangular opening 111 is formed from the manufacturing process in FIG. 2. However, due to the concerning of substrate 11 manufacturing yield, three edges of the rectangular opening 111 are cut off from the substrate 11 by laser drilling and one edge of the rectangular opening 111 is drilled with depth as half of the ceramic substrate 11 thickness. The rectangular opening 111 will be also finished in afterward descriptions.

With reference to FIG. 3, this illustrates a cross section of the package structure of the present invention after the manufacturing process shown in FIG. 2. As shown, the substrate 11 is covered conducting layers 12, 123 on both top (first) and bottom (second) surfaces, respectively. Copper plays an important role in many applications and is very versatile. Copper plating's role as an underlying coating in the decorative finishing cycle is to ‘seal’ the substrate and provide for good ‘adhesion’ of the plating to the substrate. Copper can also be used to “re-build” damaged or pitted surfaces—providing a new working surface for the finisher. On its own, copper plating can deliver an alternative look for decorative items and can be blackened, polished, or a combination of both for a ‘bronzed’ look. With the advantages aforementioned, the conducting layers 12, 123 are covered on both top (first) and bottom (second) surfaces of the ceramic substrate 11 by copper plating in the present invention.

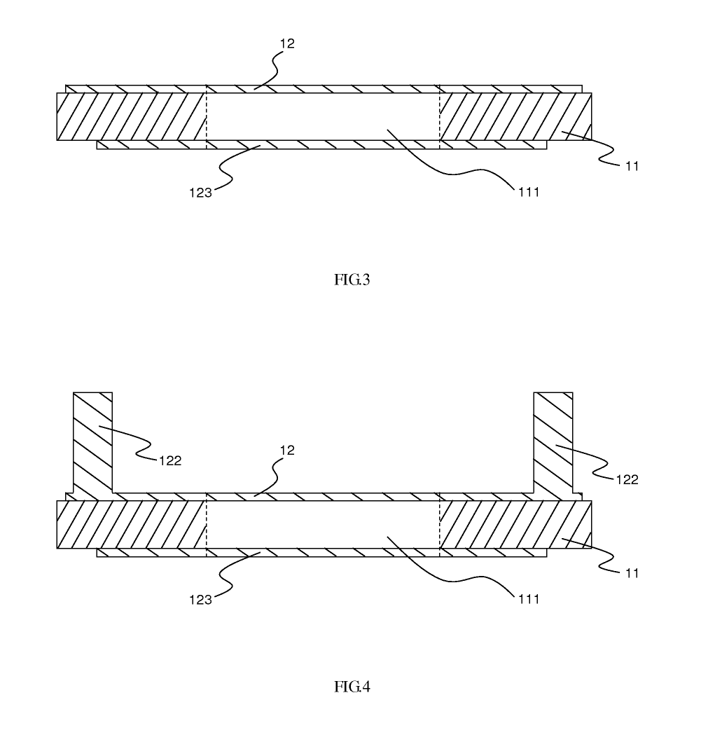

With reference to FIG. 4, this illustrates a cross section of the package structure of the present invention at the same time with the manufacturing process shown in FIG. 3. As shown, there are copper pillars 122 formed on the conducting layers 12. Also, the copper pillars 122 are disposed on the conducting layers 12 by the same copper plating process as shown in FIG. 3. So that the copper layer 12 (copper trace) and the copper pillar 122 are formed in one piece by electroplating.

Due to copper being a ductile metal with very high thermal and electrical conductivity, copper is often used in semiconductor technologies for conducting between electronic elements. However, copper is a metal being easily oxidized by air when heated. When the solar cell flip chip package structure 10 (shown in FIG. 1) works, the working temperature is high enough to affect the copper conducting layer 12 oxidized and failed. Therefore, there needs a solution to solve this problem. With reference to FIG. 5, this illustrates a cross section of the package structure of the present invention after the manufacturing process shown in FIG. 4. As shown, a surface finish layer 16 selected from a group consisting of Ag, Ag/Au, Ni/Au, Ni/Pd/Au, or any combination of the group that are widely used for surface finish, with low oxidation rate is plating on the copper conducting layer 12. Thus, the copper conducting layer 12 and external air are isolated and the copper conducting layer 12 will not be oxidized.

If the three edges of the rectangular opening 111 are cut off from the substrate 11 by laser drilling and one edge of the rectangular opening 111 is drilled with depth as half of the ceramic substrate 11 thickness in FIG. 2, the manufacturing process in FIG. 5 also comprises the step of finishing the rectangular opening 111 after cutting off the remained edge of the rectangular opening 111 with depth as half of the ceramic substrate 11 thickness.

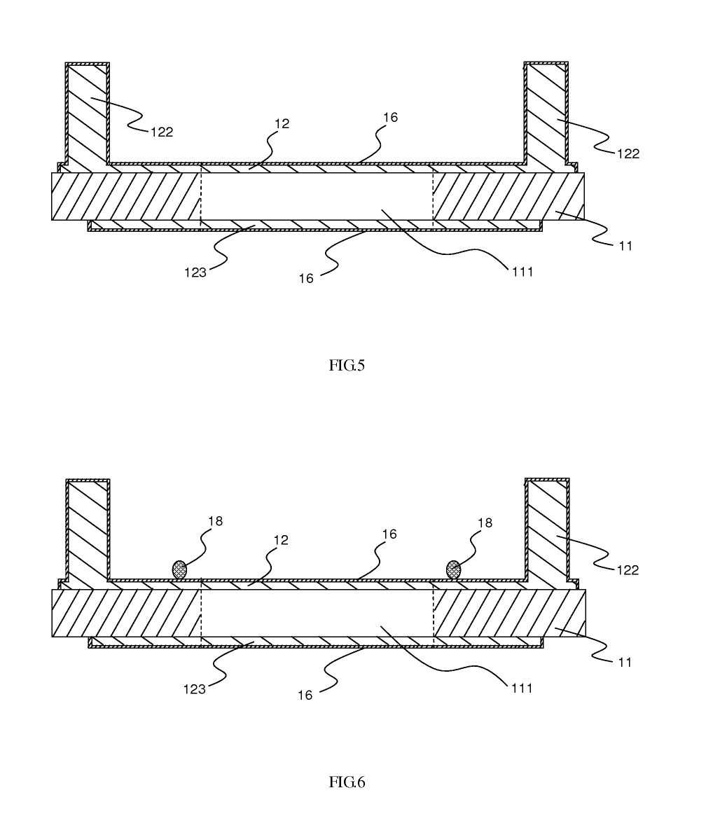

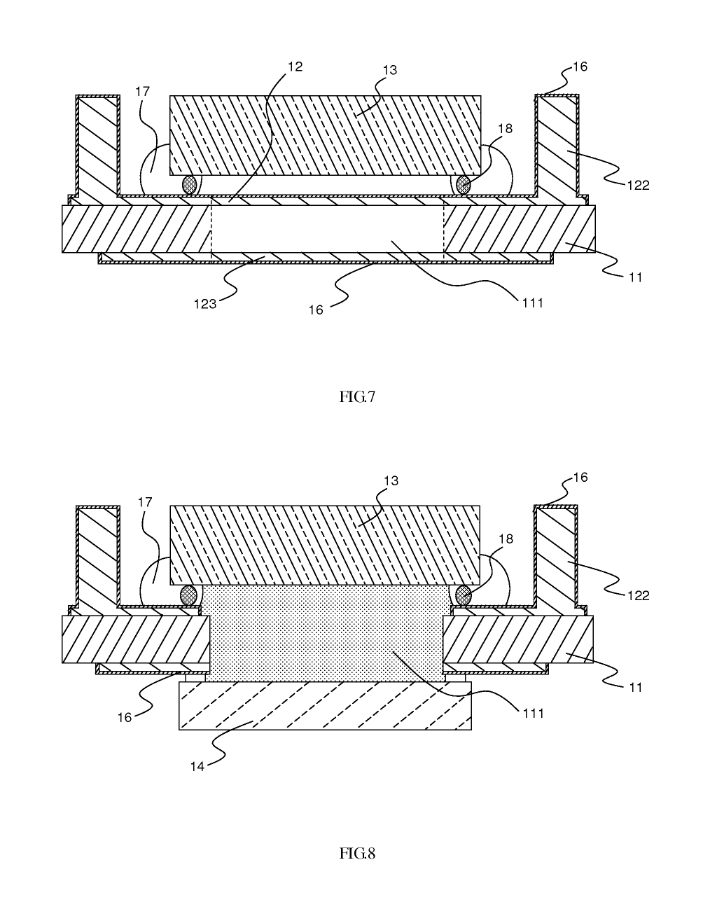

With reference to FIG. 6 and FIG. 7, these illustrate a cross section of the package structure of the present invention after the manufacturing process shown in FIG. 5 and FIG. 6, respectively. As shown, bumps 18 are plated on the surface finish layer 16 for electrically conducting to the solar cell flip chip 13. Therefore, the solar cell flip chip 13 and the copper conducting layer 12 are electrically connected through the bumps 18. The dam sealing structure 17 formed between solar cell flip chip 13 and the conducting layer 12.

With reference to FIG. 8, this illustrates a cross section of the package structure of the present invention after the manufacturing process shown in FIG. 7. As shown, glue, such as UV epoxy, is dispensed on the second surface of the ceramic substrate 11. So that the transparent layer 14, such as glass, is adhered to the second surface of the ceramic substrate 11 and covered on the rectangular opening 111. Moreover, before combining the transparent layer 14 to the second surface of the ceramic substrate 11, an optical adhesive or a silicon adhesive is filled to the full in the rectangular opening 111 for increasing the photovoltaic conversion efficiency.

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. A solar cell flip chip package structure, comprising:
a substrate having a first surface, a second surface and an opening extending from the first surface to the second surface;
a conducting layer disposed on the first surface of the substrate;
a solar cell flip chip bonded on the conducting layer;
a transparent layer attached on the second surface of the substrate; and
a storage space formed between the opening extending from the first surface to the second surface, the solar cell flip chip and the transparent layer.

2. The solar cell flip chip package structure according to claim 1, wherein the solar cell flip chip package structure of claim 1, wherein the substrate is formed by ceramic, glass, or organic materials.

3. The solar cell flip chip package structure according to claim 1, wherein the conducting layer comprises a copper trace and a copper pillar.

4. The solar cell flip chip package structure according to claim 3, wherein the copper trace and the copper pillar are formed in one piece by electroplating.

5. The solar cell flip chip package structure according to claim 3, wherein the conducting layer further comprises a surface finish layer selected from a group consisting of Ag, Ag/Au, Ni/Au, Ni/Pd/Au, or any combination of the group.

6. The solar cell flip chip package structure according to claim 1, wherein the solar cell flip chip further comprises at least one contact point for connecting to the conducting layer.

7. The solar cell flip chip package structure according to claim 6, wherein each of the at least one contact point is a bump selected from a group consisting of Au, Cu, Ag, Al, Sn or any combination of the group.

8. The solar cell flip chip package structure according to claim 7, wherein each of the at least one contact point further comprises a dam sealing structure.

9. The solar cell flip chip package structure according to claim 1, further comprising a conducting circuit formed on the second surface of the substrate.

10. The solar cell flip chip package structure according to claim 9, wherein the conducting circuit further comprises a surface finish layer selected from a group consisting of Ag, Ag/Au, Ni/Au, Ni/Pd/Au, or any combination of the group.

11. The solar cell flip chip package structure according to claim 1, wherein the storage space is further filled to the full with an optical epoxy or silicon adhesive.

12. A solar cell flip chip package structure, comprising:
a substrate having a first surface, a second surface and an opening extending from the first surface to the second surface;
a conducting layer disposed on the first surface of the substrate;
a solar cell flip chip bonded on the conducting layer;
a transparent layer formed by glass attached on the second surface of the substrate; and
a storage space formed between the opening extending from the first surface to the second surface, the solar cell flip chip and the transparent layer.

13. A method for manufacturing solar cell flip chip package structure, comprising:
forming a rectangular opening from a substrate;
covering a first conducting layer top surface of the substrate by electroplating,
plating a surface finish layer on the first conducting layer;
planting bumps on the surface finish layer for electrically conducting to a solar cell flip chip;
dispensing glue on the second surface of the substrate; and
adhering a transparent layer to the second surface of the substrate for covering on the rectangular opening.

14. The method for manufacturing solar cell flip chip package structure according to claim 13, wherein the substrate is formed by ceramic, glass, or organic materials.

15. The method for manufacturing solar cell flip chip package structure according to claim 13, wherein the first conducting layer comprises a copper trace and a copper pillar.

16. The method for manufacturing solar cell flip chip package structure according to claim 15, wherein the copper trace and the copper pillar are formed in one piece by electroplating.

17. The method for manufacturing solar cell flip chip package structure according to claim 13, wherein the surface finish layer is selected from a group consisting of Ag, Ag/Au, Ni/Au, Ni/Pd/Au, or any combination of the group.

18. The method for manufacturing solar cell flip chip package structure according to claim 13, wherein bumps are selected from a group consisting of Au, Cu, Ag, Al, Sn or any combination of the group.

19. The method for manufacturing solar cell flip chip package structure according to claim 13, wherein the transparent layer is formed by glass.

20. The method for manufacturing solar cell flip chip package structure according to claim 13, further comprising the step of filling to the full with an optical epoxy or silicon adhesive in the rectangular opening.
